(19) United States
(12) Patent Application Publication
(10) Pub. No.: US 2009/0236712 A1
(43) Pub. Date: Sep. 24, 2009

(54) IC PACKAGE HAVING REDUCED THICKNESS

(75) Inventors: Chung-Mao YEH, Taichung City (TW); Jack CHANG, Taoyuan County (TW)

Correspondence Address: BROWDY AND NEIMARK, P.L.L.C.;624 NINTH STREET, NW, SUITE 300, WASHINGTON, DC, 20001-5303, US

(73) Assignee: LINGSEN PRECISION INDUSTRIES, LTD., Taichung (TW)

(21) Appl. No.: 12/264,436

(22) Filed: Nov. 4, 2008

(30) Foreign Application Priority Data
Mar. 18, 2008 (TW) 97204642

(51) Int. Cl. H01L 23/495

(52) U.S. Cl. 257/676; 257/E23.031

(57) ABSTRACT

An IC package having reduced thickness includes a lead frame, a chip, and a plurality of bonding wires. The lead frame includes a front side, a rear side, a plurality of pins located on the front side, and a hollow portion formed on the lead frame. The chip is larger than the rear side of the lead frame. The chip includes a plurality of electrodes and is adhered to the rear side of the lead frame. The electrodes correspond to the hollow portion. The bonding wires pass through the hollow portion to be connected with the pins and the electrodes. Accordingly, the IC package can effectively take good use of the space below the lead frame, reducing the height of the bonding wires and saving the packaging space above the lead frame, and reduce the thickness of the IC package without addition of the cost and equipment.

### BACKGROUND OF THE INVENTION

1. Field of the Invention

The present invention relates generally to IC packages, and more particularly, to an IC package having reduced thickness.

2. Description of the Related Art

A conventional IC package based on the metallic lead frame as the substrate, as shown in FIG. 4, includes a lead frame 22, adhesive 24 is disposed on a chip-receiving place of the lead frame 22, a chip 21 is adhesively mounted to the lead frame 22 via the adhesive 24, bonding metallic wires 23, and a sealant 25 packaging the chip 21, the lead frame 22, and the metallic wires 23.

However, such package is limited in thickness because the chip 21 is placed on a front side of the lead frame 22, the metallic wires 23 are connected with the chip 21 and contact pads of the lead frame 22 to define a height of predetermined curvature each, and it is necessary to package the whole lead frame 22 in the sealant 25 for the purpose of preventing a rear side of the lead frame 22 from oxidization. For this reason, the thickness of the whole IC packaging cannot be reduced to restrict the applications of the IC package based on the metallic lead frame 22. Therefore, the conventional IC package is so defective that improvement is needed.

### SUMMARY OF THE INVENTION

The primary objective of the present invention is to provide an IC package having reduced thickness, in which a chip is mounted to a rear side of a metallic lead frame for reduction of thickness of the whole IC package.

The foregoing objective of the present invention is attained by the IC package composed a lead frame, a chip, and a plurality of bonding wires. The lead frame includes a front side, a rear side, a plurality of pins located on the front side, and a hollow portion formed on the lead frame. The chip is larger than the rear side of the lead frame. The chip includes a plurality of electrodes and is adhered to the rear side of the lead frame. The electrodes correspond to the hollow portion. The bonding wires pass through the hollow portion to be connected with the pins and the electrodes.

In light of the above, the present invention can effectively take good use of the space below the lead frame, reducing the height of the bonding wires and saving the packaging space above the lead frame, and reduce the thickness of the IC package without addition of the cost and equipment.

### BRIEF DESCRIPTION OF THE DRAWINGS

FIG. 1 is a perspective view of a preferred embodiment of the present invention.

FIG. 2 is a side view of the preferred embodiment of the present invention before packaged.

FIG. 3 is another view of the preferred embodiment of the present invention after packaged.

FIG. 4 is a side view of a conventional IC package.

### DETAILED DESCRIPTION OF PREFERRED EMBODIMENTS

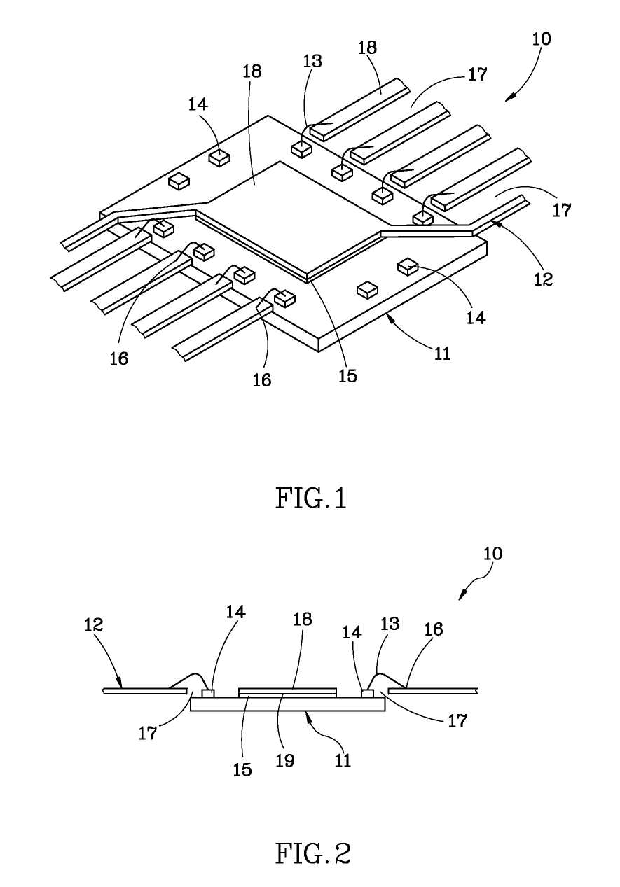

Referring to FIGS. 1-2, an IC package 10 having reduced thickness in accordance with a preferred embodiment of the present invention is composed of a lead frame 12, a chip 11, and a plurality of bonding wires 13. The lead frame 12 includes a front side 18, a rear side 19, a plurality of pins 16 located on the front side 18, and a hollow portion 17 formed on the lead frame 12. The chip 11 includes a plurality of electrodes 14. A layer of adhesive 15 is disposed between the chip 11 and the lead frame 12, being be B-Stage adhesive in this embodiment. The adhesive 15 adheres the chip 11 to the rear side 19 of the lead frame 12. The electrodes 14 correspond to the hollow portion 17. The chip 11 is larger than the rear side 19 of the lead frame 12. The bonding wires 13 pass through the hollow portion 17 to be connected with the pins 16 and the electrodes 14 respectively.

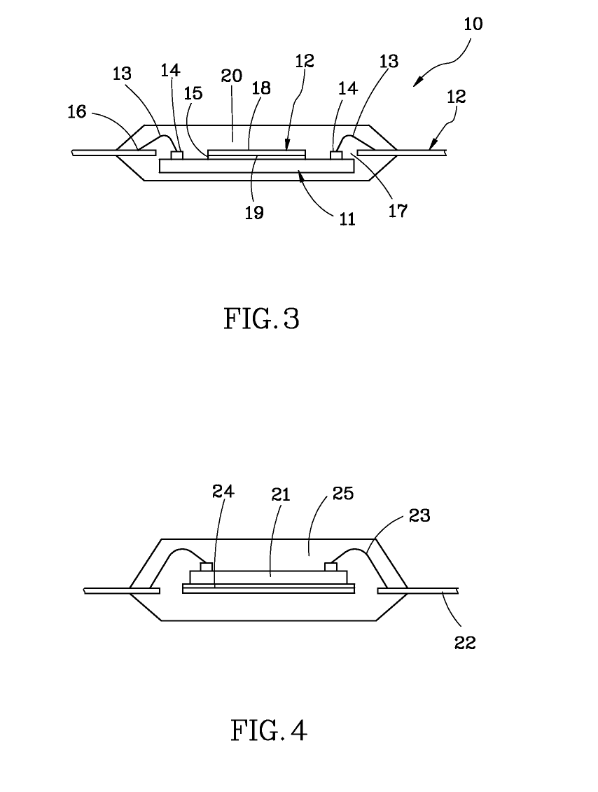

Referring to FIG. 3, when the chip 11 is adhered to the rear side 19 of the lead frame 12, the electrodes 14 correspond to the hollow portion 17 and be exposed outside the front side 18 of the lead frame 12 to enable the bonding wires 14 to pass through the hollow portion 17 to be electrically connected with the pins 16 and the electrodes 14. Finally, the chip 11, the lead frame 12, and the bonding wires 13 are packaged by a sealant 20 to become the IC package 10. Because the chip 11 is mounted to the rear side 19 of the lead frame 12, the electrodes 14 are located lower than the lead frame 12 and the location of the bonding wires 13 is lowered subject to that of the electrodes 14. Therefore, the packaging space above the lead frame 12 is decreased to reduce the thickness of the whole IC package.

In conclusion, the present invention can take good use of the space below the lead frame 12 to decrease the height of the bonding wires and to save the space above the lead frame, further reducing the thickness of the package.

Although the present invention has been described with respect to a specific preferred embodiment thereof, it is no way limited to the details of the illustrated structures but changes and modifications may be made within the scope of the appended claims.

What is claimed is:

1. An IC package having reduced thickness, comprising:
a lead frame having a front side, a rear side, a plurality of pins mounted to said front side, and a hollow portion formed thereon;
a chip larger than said rear side of said lead frame and having a plurality of electrodes, said chip having a front side adhered to said rear side of said lead frame, said electrodes corresponding to said hollow portion; and
a plurality of bonding wires passing through said hollow portion and connected with said pins and said electrodes.

2. The IC package as defined in claim 1, wherein a B-Stage adhesive is disposed between said chip and said lead frame.
